(19) United States
(12) Patent Application Publication
(10) Pub. No.: US 2023/0107130 A1
(43) Pub. Date: Apr. 6, 2023

(54) COMPUTER EXPANSION MODULE PROVIDING COOLING FOR COMPONENTS PLACED THEREIN

(71) Applicant: Nanning FuLian FuGui Precision Industrial Co., Ltd., Nanning (CN)

(72) Inventor: CHIEN-MIN HUNG, New Taipei (TW)

(21) Appl. No.: 17/490,079

(22) Filed: Sep. 30, 2021

(51) Int. Cl. H05K 7/20; G06F 1/20; G06F 1/18

(52) U.S. Cl. CPC H05K 7/2039; G06F 1/20; G06F 1/185

(57) ABSTRACT

A module functioning as an expansion of a computing device and providing a means of heat dissipation for an additional component mounted therein without disassembly of the computing device includes a mounting frame comprising a heat dissipating opening; a heat-dissipation structure is disposed on the mounting frame, a thermally-conductive sheet is disposed on a bottom surface of the heat-dissipation structure. The expansion device can be detachably inserted in the mounting frame and the expansion device contacts the thermally-conductive sheet when inserted in the mounting frame.

### FIELD

The subject matter herein generally relates to expansion modules for electronic apparatuses.

### BACKGROUND

The storage device of computers has gradually changed from mechanical hard drives to solid state disks, which can improve data transmission efficiency. However, the M.2 solid state disk, for example, must be inserted into the main board in the casing of the computer. When installing a solid state disk, a user needs to open the casing to install the solid state disk, which may be inconvenient.

In addition, because the solid state disk generates more heat, to increase heat dissipation performance of the solid state disk may be problematic.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a perspective view of an electronic apparatus and an expansion module in accordance with an embodiment of the present disclosure.

FIG. 2 is a perspective view of a mounting device of the expansion module of FIG. 1.

FIG. 3 is a cross-sectional view of the mounting device of FIG. 2.

FIG. 4 is an exploded view of the mounting device of FIG. 2.

FIG. 5 is a perspective view of an expansion device of the expansion module of FIG. 1.

FIG. 6 is a cross-sectional view of the expansion device of FIG. 5.

FIG. 7 is an exploded view of the expansion device of FIG. 5.

FIG. 8 is a cross-sectional view of the expansion module of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connected” is defined as directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

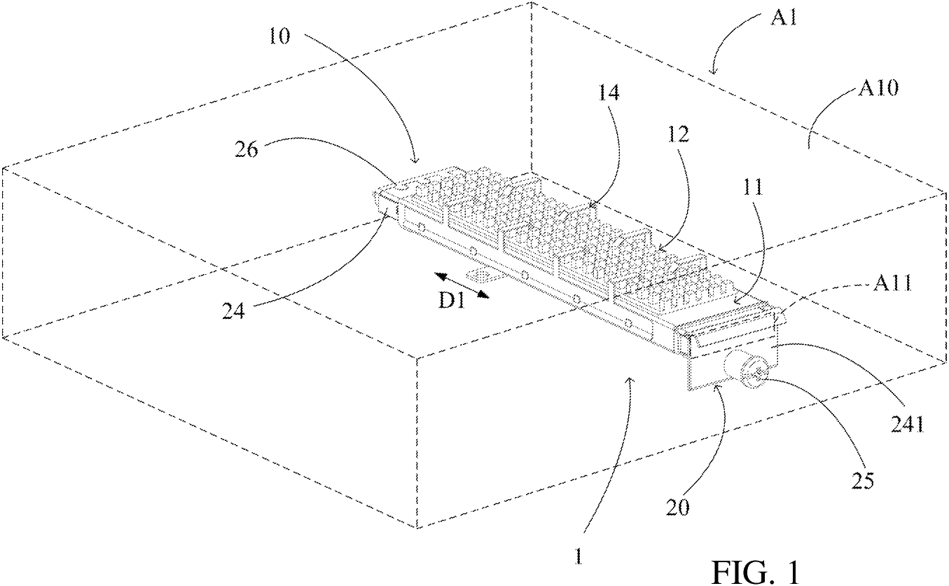

FIG. 1 is a perspective view of an electronic apparatus A1 and an expansion module 1 in accordance with an embodiment of the present disclosure. The electronic apparatus A1 can be a computer, a server, or a router, but it is not limited thereto. The electronic apparatus A1 includes a casing A10. One side wall of the casing A10 includes an inserting opening A11. The expansion module 11 includes a mounting device 10 and an expansion device 20.

The mounting device 10 is affixed in the casing A10 of the electronic apparatus A1, and corresponds to the inserting opening A11 of the casing A10. The expansion device 20 is detachably inserted into the mounting frame 11 via the inserting opening A11. In this embodiment, the expansion device 20 is a solid state disk (SSD), but it is not limited thereto. In another embodiment, the expansion device 20 can be a network communication device. The expansion device 20 is plugged into the electronic apparatus A1 via the mounting device 10.

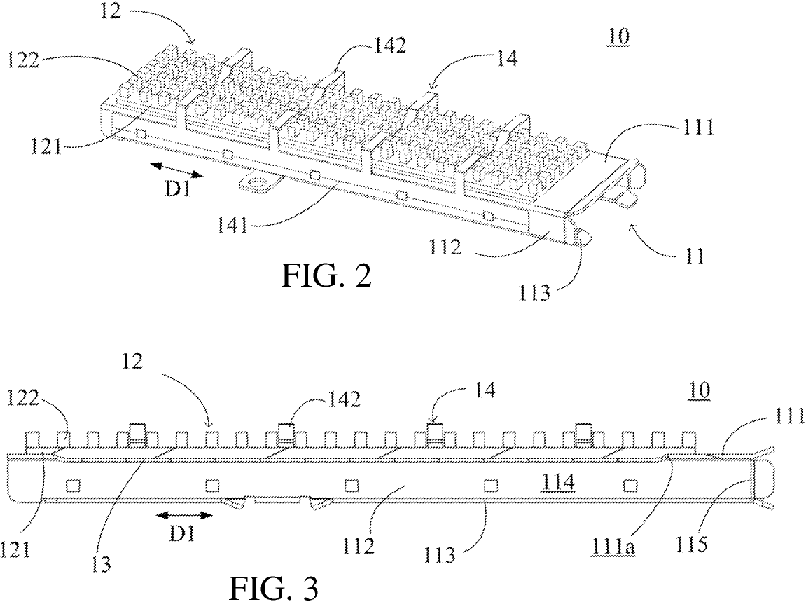

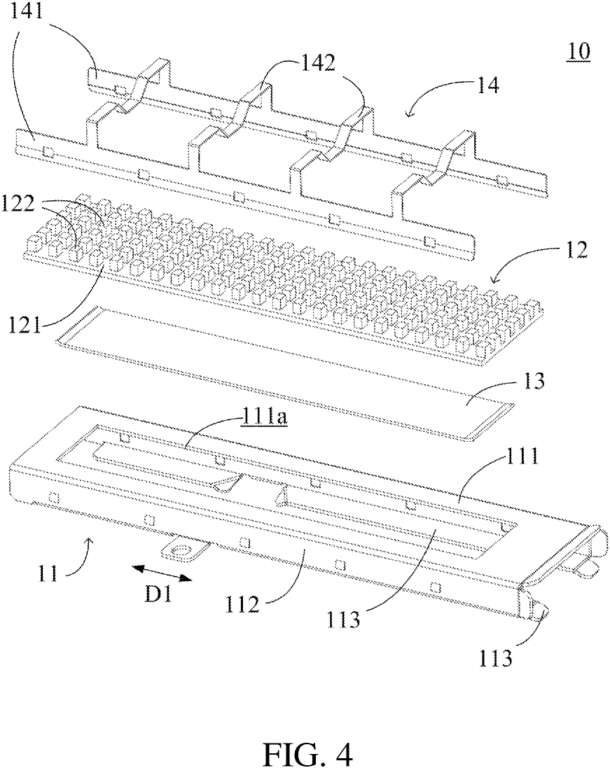

FIG. 2 is a perspective view of the mounting device 10 of FIG. 1. FIG. 3 is a cross-sectional view of the mounting device 10 of FIG. 2. FIG. 4 is an exploded view of the mounting device 10 of FIG. 2. The mounting device 10 includes a mounting frame 11, a heat-dissipation structure 12, a thermally-conductive sheet 13, and an elastic clamp 14. The mounting frame 11 is a structure which is elongated in an extension direction D1. In this embodiment, the mounting frame 11 is a metal plate which is bent and stamped.

The mounting frame 11 includes a main plate 111, two connection walls 112, and two support plates 113. The main plate 111, the connection walls 112, and the support plates 113 are elongated in the extension direction D1. The main plate 111 includes a dissipation opening 111a. The dissipation opening 111a penetrates through the main plate 111, and is elongated in the extension direction D1. In this embodiment, the length of the dissipation opening 111a in the extension direction D1 is at least 0.7 times the length of main plate 111 in the extension direction D1.

The connection walls 112 are connected to two opposite longitudinal edges of the main plate 111. The connection walls 112 extend perpendicular to the main plate 111, and parallel to each other. The support plates 113 are perpendicular to the connection walls 112, and parallel to the main plate 111. In this embodiment, the support plates 113 are separated from each other. In another embodiment, the support plates 113 are connected to each other. The main plate 111, the connection walls 112, and the support plates 113 form a slot 114. The slot 114 is in communication with the front opening 115 and the dissipation opening 111a of the mounting frame 11. The expansion device 20 is inserted into the slot 114 via the front opening 115. In this embodiment, when the expansion device 20 is inserted in to the slot 114, the expansion device 20 is fastened between the main plate 111, the connection wall 112, and the support plate 113.

The heat-dissipation structure 12 is disposed on the main plate 111 of the mounting frame 11. The heat-dissipation structure 12 is elongated in the extension direction D1. The heat-dissipation structure 12 includes a heat-dissipation plate 121 and heat-dissipation protrusions 122. The heat-dissipation plate 121 is parallel to the main plate 111, and covers the dissipation opening 111a. In this embodiment, the bottom surface of the heat-dissipation plate 121 contacts the top surface of the main plate 111. The heat-dissipation protrusions 122 are disposed on the top surface of the heat-dissipation plate 121, and separated from each other. The heat-dissipation plate 121 and the heat-dissipation protrusions 122 can be made of the same thermally conductive materials, and are formed as a single piece. In this embodiment, the heat-dissipation protrusions 122 are arrayed on the top surface of the heat-dissipation plate 121. In some embodiments, the heat-dissipation protrusions 122 are fins, and parallel to each other.

The thermally-conductive sheet 13 is disposed on the bottom surface of the heat-dissipation plate 121 of the heat-dissipation structure 12, and in the dissipation opening 111a. The thermally-conductive sheet 13 is an elongated structure in the extension direction D1. The length of thermally-conductive sheet 13 in the extension direction D1 is substantially the same as the length of the dissipation opening 111a.

In some embodiments, the length of the thermally-conductive sheet 13 in the extension direction D1 is at least 0.8 times the length of the dissipation opening 111a. In this embodiment, the thermally-conductive sheet 13 is a graphite sheet to increase the heat-dissipation efficiency between the expansion device 20 and the heat-dissipation structure 12. In some embodiments, the thermally-conductive sheet 13 is adhered to the heat-dissipation plate 121 via thermally conductive adhesive.

The elastic clamp 14 is fastened to the mounting frame 11, and clamps the heat-dissipation structure 12 to the main plate 111 of the mounting frame 11. The elastic clamp 14 can be made of sheet metal. The elastic clamp 14 includes two retaining elements 141 and elastic sheets 142.

The retaining elements 141 are elongated in the extension direction D1. The retaining elements 141 are fastened to the connection walls 112 of the mounting frame 11. The elastic sheets 142 are connected to the retaining elements 141, and abut the heat-dissipation structure 12. In this embodiment, each elastic sheet 142 is M-shaped. Ends of the elastic sheet 142 are connected to the retaining elements 141. The central segment of the elastic sheet 142 abuts the heat-dissipation plate 121 of the heat-dissipation structure 12. The retaining elements 141 and the elastic sheets 142 are formed as a single piece of the same materials.

In this embodiment, the heat-dissipation structure 12 can be firmly affixed to the main plate 111 by the elastic clamp 14. The elastic clamps 14 provide pressure on the heat-dissipation structure 12, so that the thermally-conductive sheet 13 can be tightly connected to the heat-dissipation structure 12 and the expansion module 1, thereby providing the expansion module 1 with good heat dissipation efficiency.

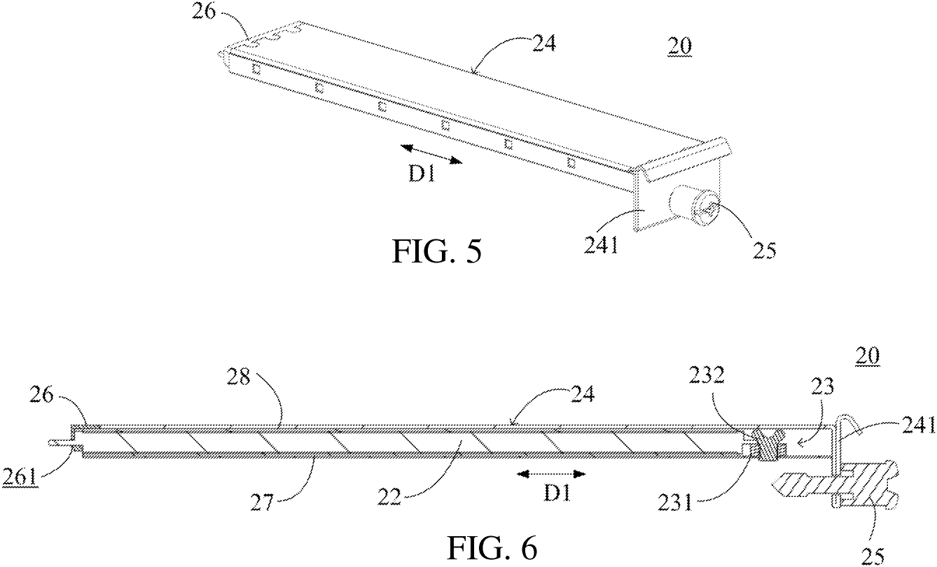

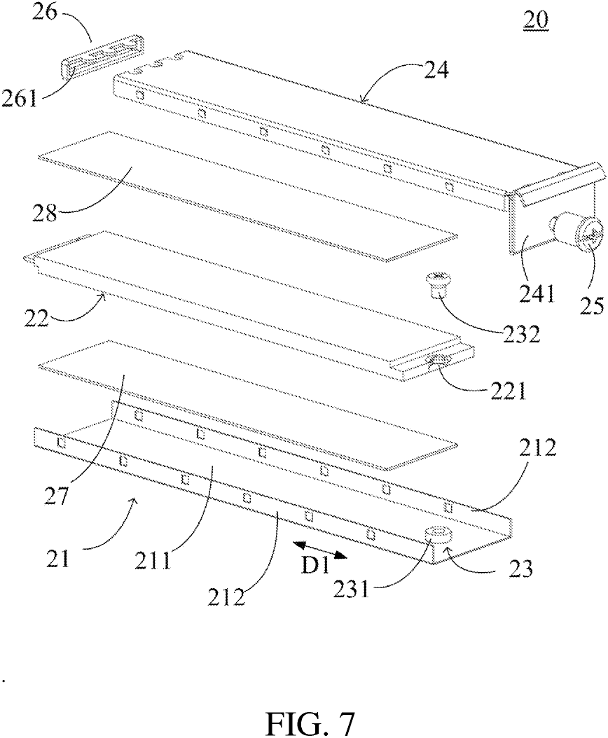

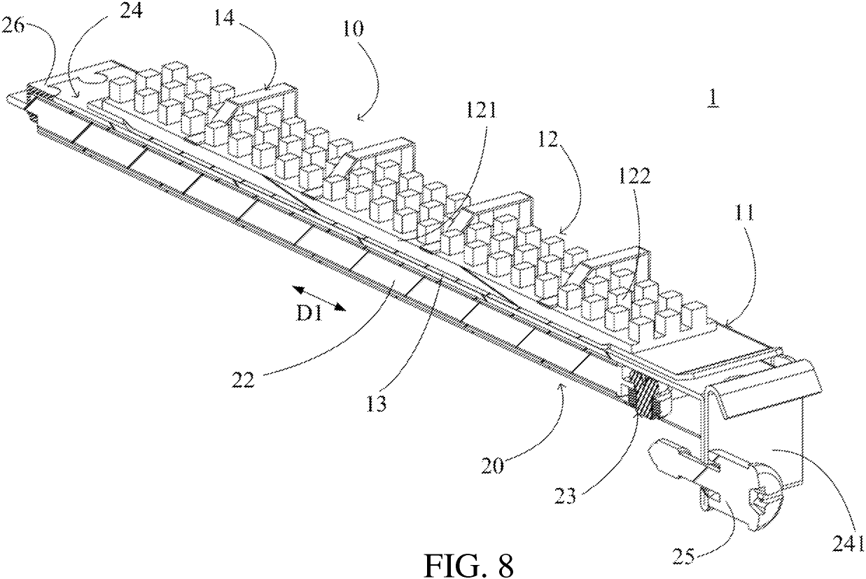

FIG. 5 is a perspective view of the expansion device 20 of FIG. 1. FIG. 6 is a cross-sectional view of the expansion device 20 of FIG. 5. FIG. 7 is an exploded view of the expansion device 20 of FIG. 5. FIG. 8 is a cross-sectional view of the expansion module 1 of FIG. 1. The expansion device 20 includes a lower cover 21, an expansion card 22, a positioning structure 23, an upper cover 24, a fastener 25, a restriction element 26, a lower thermal pad 27, and an upper thermal pad 28.

The lower cover 21, the expansion card 22, the upper cover 24, the lower thermal pad 27, and the upper thermal pad 28 are elongated in the extension direction D1. The lower cover 21 includes a bottom plate 211 and two side walls 212. The bottom plate 211 and two side walls 212 are elongated in the extension direction D1. The side walls 212 are perpendicular to the bottom plate 211, and parallel to each other. The bottom plate 211 and the side walls 212 form a U-shaped structure.

The expansion card 22 is put in the lower cover 21 between the side walls 212. The expansion card 22 may be a solid state disk (SSD), but it is not limited thereto. In another embodiment, the expansion card 22 is a network card. The positioning structure 23 is disposed on the bottom plate 211 of the lower cover 21. The expansion card 22 includes a positioning groove 221 corresponding to the positioning structure 23. When the expansion card 22 is mounted on the lower cover 21, the positioning structure 23 is in the positioning groove 221 so as to limit the placement of the expansion card 22 in the expansion device 20.

In this embodiment, the positioning structure 23 includes a positioning protrusion 231 and a screw 232. The positioning protrusion 231 is affixed to the bottom plate 211 of the lower cover 21. The screw 232 is fastened to the positioning protrusion 231 via positioning groove 221, so as to affix the expansion card 22 to the lower cover 21. In this embodiment, by locking the positioning protrusion 231 in different positions, the lower cover 21 can be used with expansion cards 22 of different specifications.

The upper cover 24 is fastened to the side wall of the upper cover 24, and includes a front plate 241 covering the front end of the lower cover 21. The expansion card 22 is between the lower cover 21 and the upper cover 24. When the expansion device 20 is inserted into the mounting frame 11, the upper cover 24 of the expansion device 20 contacts the thermally-conductive sheet 13. The fastener 25 is rotatably disposed on the front plate 241, and locks the casing A10 in FIG. 1 to prevent the expansion device 20 separating from the mounting device 10.

The fastener 25 is rotatably disposed on the front plate 241, and is used to lock the casing A10 in FIG. 1 to prevent the expansion device 20 separating from the mounting device 10. The restriction element 26 is detachably disposed on the rear ends of the upper cover 24 and the lower cover 21. The restriction element 26 includes a restriction slot 261. The rear end of the expansion card 22 is inserted in the restriction slot 261, so that the expansion card 22 is firmly installed in the expansion module 1. In this embodiment, by aligning the restriction element 26 with the restriction slot 261 in different positions and sizes, the lower cover 21 and the upper cover 24 can be used with expansion cards 22 of different specifications.

In this embodiment, the lower cover 21 and the upper cover 24 can be made of metal materials. The lower thermal pad 27 is disposed between the lower cover 21 and the expansion card 22, so as to improve the heat-dissipation efficiency between the lower cover 21 and expansion card 22. The upper thermal pad 28 is between the upper cover 24 and the expansion card 22, so that the heat-dissipation efficiency between the upper cover 24 and the expansion card 22 is improved.

The expansion device of the present disclosure is mounted to the mounting device in the casing through the insertion opening of the casing of the electronic apparatus, thus the casing of the electronic apparatus does not need to be opened to install the expansion device to the electronic apparatus. In addition, the mounting device can provide good heat-dissipation performance, which meets the heat dissipation requirements of a high-performance component or device.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. An expansion module comprising:
a mounting frame comprising a dissipation opening;
a heat-dissipation structure disposed on the mounting frame;
a thermally-conductive sheet disposed on a bottom surface of the heat-dissipation structure, and in the dissipation opening; and
an expansion device detachably inserted in the mounting frame,
wherein when the expansion device is inserted in the mounting frame, the expansion device contacts the thermally-conductive sheet.

2. The expansion module as claimed in claim 1, wherein the mounting frame comprises a slot and a front opening, the slot is in communication with each of the front opening and the dissipation opening, the expansion device is insertable in the slot via the front opening.

3. The expansion module as claimed in claim 1, wherein the heat-dissipation structure comprises a heat-dissipation plate contacting the mounting frame and a plurality of heat-dissipation protrusions disposed on the heat-dissipation plate, wherein the heat-dissipation plate covers the dissipation opening.

4. The expansion module as claimed in claim 1, further comprising an elastic clamp fastened to the mounting frame, and configured to clamp the heat-dissipation structure to the mounting frame.

5. The expansion module as claimed in claim 4, wherein the elastic clamp comprises:
two retaining elements fastened to two opposite sides of the mounting frame, respectively; and
an elastic sheet connected to the retaining element, and abutting the heat-dissipation structure.

6. The expansion module as claimed in claim 1, wherein the expansion device comprises:
a lower cover;
an upper cover fastened to the upper cover, and comprising a front plate covering a front end of the lower cover;
a fastener disposed on the front plate; and
an expansion card disposed between the lower cover and the upper cover.

7. The expansion module as claimed in claim 6, wherein the expansion device further comprises:
a lower thermal pad between the lower cover and the expansion card; and
an upper thermal pad between the upper cover and the expansion card.

8. The expansion module as claimed in claim 6, further comprising a positioning structure disposed on the lower cover, the expansion card comprising a positioning groove corresponding to the positioning structure.

9. The expansion module as claimed in claim 6, further comprising a restriction element detachably disposed on rear ends of the upper cover and the lower cover, and comprising a restriction slot, wherein a rear end of the expansion card is insertable into the restriction slot.

10. The expansion module as claimed in claim 1, wherein the mounting frame is configured to be affixed in a casing of the electronic apparatus, and corresponding to an inserting opening of the casing, and the expansion device is insertable into the mounting frame via the inserting opening.
